(19) United States
(12) Patent Application Publication
(10) Pub. No.: US 2026/0290452 A1
(43) Pub. Date: Sep. 24, 2026

(54) IN-MEMORY COMPUTING ARCHITECTURE AND OPERATING METHOD THEREOF

(71) Applicant: PEKING UNIVERSITY, Beijing (CN)

(72) Inventors: Zongwei WANG, Beijing (CN); Yimao CAI, Beijing (CN); Tianyang LUO, Beijing (CN); Jinshan LI, Beijing (CN); Ru HUANG, Beijing (CN)

(73) Assignee: PEKING UNIVERSITY, Beijing (CN)

(21) Appl. No.: 19/572,587

(22) Filed: Mar. 19, 2026

(30) Foreign Application Priority Data
Mar. 20, 2025 (CN) 202510336301.X

(51) Int. Cl. G11C 13/00

(52) U.S. Cl. CPC G11C 13/004; G11C 13/0026; G11C 13/0028; G11C 13/0038; G11C 13/0069; G11C 13/0097

(57) ABSTRACT

The present disclosure discloses an in-memory computing architecture and an operating method thereof. The in-memory computing architecture includes a memory array, a driving and sensing circuit, and a peripheral circuit. The memory array includes memory strings, source lines, word lines, and bit lines. The memory string includes memory cells connected in series. The memory cell includes a memory transistor and a bypass resistor, which are connected in parallel. The memory string is connected to the source line and the bit line. A control terminal of the memory cell is connected to the word line. The driving and sensing circuit is connected to the source line. The peripheral circuit is connected to the word line and the bit line.

### CROSS-REFERENCE TO RELATED APPLICATIONS

This application claims priority to Chinese Patent Application No. 202510336301.X, filed on Mar. 20, 2025, entitled “IN-MEMORY COMPUTING DEVICE AND OPERATING STRATEGY THEREOF”, the entire contents of which are incorporated herein by reference.

### TECHNICAL FIELD

The present disclosure relates to the field of integrated circuits, and in particular, to an in-memory computing architecture and an operating method thereof.

### BACKGROUND

NOT AND Flash (NAND Flash) is a type of non-volatile memory. NAND Flash memory has the advantages of high storage density, low cost, long service life, and low power consumption, and is widely used in fields such as solid state drives, USB flash drives, memory cards, and embedded systems.

At present, NAND Flash memory improves storage density through vertical stacking and connects memory cells in series using a vertical structure, thereby achieving relatively high storage density and relatively low cost.

### SUMMARY

In a first aspect, an in-memory computing architecture is provided in the present disclosure. The in-memory computing architecture includes a memory array, a driving and sensing circuit, and a peripheral circuit. The memory array includes a plurality of memory strings, a plurality of source lines, a plurality of word lines, and a plurality of bit lines. Each of the plurality of memory strings includes a plurality of memory cells connected in series along a first direction. Each of the plurality of memory cells comprises a memory transistor and a bypass resistor. The memory transistor and the bypass resistor are connected in parallel. Each of the plurality of memory strings is connected to the corresponding source line of the plurality of source lines through a bottom select transistor. Each of the plurality of memory strings is connected to the corresponding bit line of the plurality of bit lines through a top select transistor. A control terminal of each of the plurality of memory cells is connected to the corresponding word line. The driving and sensing circuit is connected to the source line. The driving and sensing circuit is configured to provide a read current to the source line, sense a voltage signal of the source line, and output a digital signal of the voltage signal of the source line. The peripheral circuit is connected to the word lines and the bit lines. The peripheral circuit is configured to control the voltages of the word lines and the bit lines.

In an embodiment, each of the plurality of source lines is disposed below the corresponding memory string of the plurality of memory strings. The plurality of source lines are arranged along a second direction and a third direction perpendicular to the first direction. Each of the plurality of source lines is connected to a first terminal of the bottom select transistor of the corresponding memory string of the plurality of memory strings. The plurality of word lines are arranged along the first direction. Each of the plurality of word lines is connected to the control terminal of the corresponding memory cell of the plurality of memory cells. Each of the plurality of word lines and the corresponding memory cell are arranged on the same layer. Each of the plurality of bit lines is disposed above the corresponding memory string of the plurality of memory strings. Each of the plurality of bit lines extends along the second direction and is arranged along the third direction. Each of the bit lines is connected to a second terminal of the top select transistor of the corresponding memory string arranged along the second direction. The plurality of the memory strings arranged along the second direction are connected to the plurality of the source lines arranged along the second direction, respectively.

In an embodiment, a resistance value of the bypass resistor is greater than a channel equivalent resistance value of the memory transistor when turned on, and less than a channel equivalent resistance value of the memory transistor when turned off.

In an embodiment, along the first direction, the driving and sensing circuit is integrated below the plurality of source lines. The peripheral circuit is integrated above the plurality of bit lines. The driving and sensing circuit includes a current generation circuit, a current mirror, a source follower, and an analog-to-digital converter. The current generation circuit is configured to generate a read current. The current mirror is configured to duplicate the read current and provide the read current to the source line. The source follower is configured to read the voltage signal of the source line. The analog-to-digital converter is configured to convert the voltage signal into a digital signal and output the digital signal.

In an embodiment, the in-memory computing architecture further includes a control logic circuit. The control logic circuit is connected to the driving and sensing circuit and the peripheral circuit. The control logic circuit is configured to deploy weight information to the plurality of memory cells according to a weight writing strategy, with a threshold voltage of the memory cell representing the weight information. The control logic circuit is configured to apply read voltages or turn-on voltages to the plurality of word lines. The control logic circuit is configured to input a read current to the source line corresponding to the plurality of word lines. The control logic circuit is configured to calculate the number of turned-off memory transistors in the corresponding memory string according to a voltage drop generated by the source line and output a computation result.

In a second aspect, an operating method of the in-memory computing architecture is provided in the present disclosure. The in-memory computing architecture includes a memory array. The memory array includes a plurality of memory strings, a plurality of source lines, a plurality of word lines, and a plurality of bit lines. Each of the plurality of memory strings includes a plurality of memory cells connected in series along a first direction. Each of the plurality of memory cells includes a memory transistor and a bypass resistor. The memory transistor and the bypass resistor are connected in parallel. Each of the plurality of memory strings is connected to the corresponding source line of the plurality of source lines through a bottom select transistor. Each of the plurality of memory strings is connected to the corresponding bit line of the plurality of bit lines through a top select transistor. A control terminal of each of the plurality of memory cells is connected to the corresponding word line. The in-memory computing architecture further includes a driving and sensing circuit connected to the source line. The driving and sensing circuit is configured to provide a read current to the source line, sense a voltage signal of the source line, and output a digital signal of the voltage signal of the source line. The in-memory computing architecture further includes a peripheral circuit connected to the word lines and the bit lines. The peripheral circuit is configured to control voltages of the word lines and the bit lines. The operating method of the in-memory computing architecture includes deploying weight information to the plurality of memory cells according to a weight writing strategy, with threshold voltages of the plurality of memory cells representing the weight information. The operating method of the in-memory computing architecture includes applying read voltages or turn-on voltages to the plurality of word lines, and inputting a read current to the source line corresponding to the plurality of word lines. The operating method of the in-memory computing architecture includes calculating the number of turned-off memory transistors in the corresponding memory string according to a voltage drop generated by the source line, and outputting a computation result.

In an embodiment, the step of deploying weight information to the plurality of memory cells according to a weight writing strategy includes encoding a plurality of weight elements of a weight matrix into binary values of a weight 1 or a weight 0. The step of deploying weight information to the plurality of memory cells according to a weight writing strategy further includes applying a program voltage or an erase voltage to each of the plurality of memory cells corresponding to each of the plurality of weight elements according to a mapping relationship between the weight matrix and the plurality of memory cells. The step of deploying weight information to the plurality of memory cells according to a weight writing strategy further includes adjusting a threshold voltage of each of the plurality of memory cells to a higher threshold voltage or a lower threshold voltage. The higher threshold voltage corresponds to the weight 1. The lower threshold voltage corresponds to the weight 0.

In an embodiment, the step of applying read voltages or turn-on voltages to the plurality of word lines includes encoding a plurality of weight elements of each activation vector of the weight matrix into binary values. The step of applying read voltages or turn-on voltages to the plurality of word lines further includes applying the read voltages to word lines corresponding to encoded activation values 1 and applying the turn-on voltages to word lines corresponding to encoded activation values 0, according to a mapping relationship between the activation vector and the plurality of word lines. The turn-on voltages are greater than the read voltages.

In an embodiment, the step of applying read voltages or turn-on voltages to the plurality of word lines, and inputting a read current to the source line further includes adjusting the turn-on voltages and read current of the plurality of word lines, so that when the memory transistor is turned on, a current of the memory cell flows through the memory transistor, and when the memory transistor is turned off, the current of the memory cell flows through the bypass resistor, to generate a voltage drop across two sides of the memory cell.

In an embodiment, the step of calculating the number of turned-off memory transistors in the corresponding memory string according to a voltage drop generated by the source line, and outputting a computation result includes performing a multiplication on the plurality of weight elements corresponding to the plurality of memory cells and activation values of the plurality of word lines connected to the plurality of memory cell, respectively, to obtain voltage drops of the memory cells as each of 1 or 0. The step of calculating the number of turned-off memory transistors in the corresponding memory string according to a voltage drop generated by the source line, and outputting a computation result further includes performing an addition on the voltage drops of the plurality of memory cells of each of the plurality of memory strings, to obtain the number of turned-off memory transistors in each of the plurality of memory strings.

In a third aspect, a memory array is provided in the present disclosure. The memory array includes a plurality of memory strings, a plurality of source lines, a plurality of word lines, and a plurality of bit lines. Each of the plurality of memory strings includes a plurality of memory cells connected in series along a first direction. Each of the plurality of memory cells includes a memory transistor and a bypass resistor. The memory transistor and the bypass resistor are connected in parallel. Each of the plurality of memory strings is connected to the corresponding source line of the plurality of source lines through a bottom select transistor. Each of the plurality of memory strings is connected to the corresponding bit line of the plurality of bit lines through a top select transistor. A control terminal of each of the plurality of memory cells is connected to the corresponding word line.

### BRIEF DESCRIPTION OF DRAWINGS

To more clearly illustrate the technical solutions in embodiments of the present disclosure or the prior art, the accompanying drawings required for the description of the embodiments or the prior art will be briefly introduced below. Obviously, the accompanying drawings in the following description only involve some embodiments of the present disclosure, and for those of ordinary skill in the art, other drawings can also be obtained according to these accompanying drawings without inventive efforts.

FIG. 1 is an architecture diagram of an in-memory computing architecture provided in an embodiment.

FIG. 2 is a circuit diagram of a memory array provided in an embodiment.

FIG. 3 is a schematic circuit diagram of a memory array provided in an embodiment.

FIG. 4 is a circuit diagram of a driving and sensing circuit provided in an embodiment.

FIG. 5 is a schematic flowchart of an operating method of an in-memory computing architecture of a memory provided in an embodiment.

FIG. 6 is a circuit diagram involved in an operating method of an in-memory computing architecture provided in an embodiment.

FIG. 7 is a schematic diagram of weight encoding provided in an embodiment.

FIG. 8 is an internal structure diagram of an electronic device provided in an embodiment.

### DETAILED DESCRIPTION

To facilitate understanding of the present disclosure, the present disclosure will be described more fully below with reference to the relevant accompanying drawings. Preferred embodiments of the present disclosure are shown in the accompanying drawings. However, the present disclosure may be implemented in many different forms and is not limited to the embodiments described herein. On the contrary, these embodiments are provided to disclose the present disclosure more comprehensively.

Unless otherwise defined, all technical and scientific terms used herein have the same meaning as commonly understood by one of ordinary skill in the art to which the present disclosure belongs. The terms used herein in the specification of the present disclosure are only for the purpose of describing specific embodiments, and are not intended to limit the present disclosure.

Modern computers usually adopt the von Neumann architecture with separated computation and storage, where data needs to be transmitted between a processor and a memory. In recent years, with the rapid development of artificial intelligence, the scale of neural network models has been expanding continuously. Large language models (LLMs) based on the transformer neural network structure with an attention mechanism often have a parameter count of billions to trillions, so the computation demand and data movement requirement during inference have increased sharply. At the same time, the demand for deploying large models on edge devices such as Artificial Intelligence of Things (AIoT) devices, smartphones, and autonomous driving systems continues to grow. In the case of limited storage and computation resources, prominent power consumption constraints, and strict latency requirements on the edge side, the von Neumann architecture that requires frequent data transmission has low efficiency. Most existing in-memory computing solutions use storage media such as Resistive Random Access Memory (RRAM) and Static Random-Access Memory (SRAM), but these media have low storage density, limited array scale, and high manufacturing cost, which are not suitable for the potential computation demand of large model inference on the edge side.

NAND Flash memory, due to its high storage density, low cost, ultra-large array scale, and multi-layer stacking structure, has great potential in storing model parameters, providing low-cost computing power, and saving chip area. In in-memory computing of NAND Flash, the current mainstream solutions adopt a current-domain operating method.

The computation of the current-domain operating method is similar to the operation of NAND Flash in memory, where weights are stored in the array, activation values are input in the form of voltage amplitude, and the multiply-accumulate result is output in the form of current sum. However, the reading of NAND Flash by the current-domain operating method can only turn on one layer of memory cells at a time, and a massive number of memory cells cannot be effectively parallelized during in-memory computing. A single computation of the current mainstream in-memory computing strategy can only utilize 0.14% to 0.43% of the total cells in the array, resulting in very low computation parallelism and computation efficiency. However, NAND Flash memory has very low computation parallelism and computation efficiency. Thus, how to effectively improve the computation efficiency of NAND Flash is a critical technical problem to be addressed. Accordingly, it is necessary to provide an in-memory computing architecture and an operating method thereof to address the problems in the prior art.

In an embodiment, an in-memory computing architecture is provided in the present disclosure. As shown in FIG. 1, the in-memory computing architecture includes a memory array 100, a driving and sensing circuit 200, and a peripheral circuit 300.

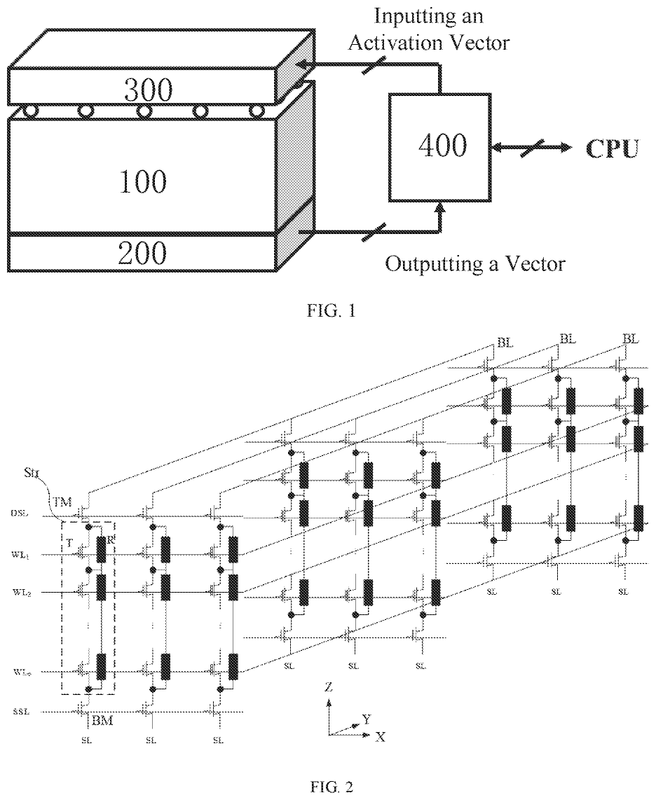

As shown in FIG. 2, the memory array 100 includes a plurality of memory strings Str, a plurality of source lines SL, a plurality of word lines WL, and a plurality of bit lines BL. The memory string Str includes a plurality of memory cells T-R connected in series along a first direction Y. The memory cell T-R includes a memory transistor T and a bypass resistor R. The memory transistor T and the bypass resistor R are connected in parallel. The memory string Str is connected to the source line SL through a bottom select transistor BM, and connected to the bit line BL through a top select transistor TM. Each memory string Str can be independently controlled and accessed through the corresponding source line SL and bit line BL. A control terminal of the memory cell T-R (gate of the memory transistor T) is connected to the word line WL. The on-off state of the memory transistor T in the memory cell T-R can be controlled by controlling the voltage change of the corresponding word line WL, thereby realizing the reading or writing of data.

In this embodiment, each memory string Str includes n memory cells T-R (n≥1) vertically stacked along a first direction Z. Along the first direction Z, the memory transistors T of the memory cells T-R are connected in series sequentially along the first direction Z. The bypass resistors R of the memory cells T-R are connected in series sequentially along the first direction Z. On a plane perpendicular to the first direction Z, the memory transistor T includes a channel layer, a tunneling layer, a charge trapping layer, a gate dielectric layer, and a control gate, which are sequentially surrounding and covering the circumferential plane of the bypass resistor R.

Along the first direction Z, n word lines WL₁ to WLₙ are arranged at intervals and are connected to the control gates of the n memory transistors T of the memory string Str, respectively.

The driving and sensing circuit 200 is connected to the source lines SL. The driving and sensing circuit 200 is configured to provide a read current Iref to the source line SL, sense a voltage signal of the source line SL, convert an output voltage signal into a digital signal, and output a digital signal of the voltage signal of the source line SL, which improves the efficiency and speed of data processing.

The peripheral circuit 300 is connected to the word lines WL and the bit lines BL. The peripheral circuit 300 is configured to control voltages of the word lines WL and the bit lines BL. The peripheral circuit 300 is configured to realize reading and writing of the memory cell T-R and cooperate with the driving and sensing circuit 200 to realize data transmission.

The in-memory computing architecture of this embodiment integrates the memory array 100, the driving and sensing circuit 200, and the peripheral circuit 300, realizing a high integration of data storage and computation. The in-memory computing architecture can directly process data inside the memory array 100 without reading the data out to an external processor for computation, and avoids latency and power consumption caused by external data transmission. The in-memory computing architecture of this embodiment can perform computation tasks by using the structure of the memory array 100, perform operations on multiple memory strings Str in parallel, read a computation result from the source line by detecting a voltage change of the source line SL corresponding to each memory cell T-R, and achieve high computation efficiency.

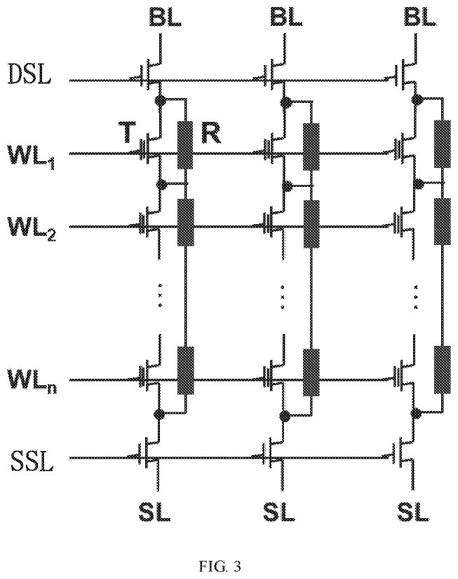

In some embodiments, as shown in FIG. 2 and FIG. 3, the source lines SL are arranged below the memory strings Str. The source lines SL are arranged along a second direction Y and a third direction X perpendicular to the first direction Z. The source line SL is connected to a first terminal of the bottom select transistor BM of the memory string Str. In this embodiment, the first terminal of the bottom select transistor BM is a source terminal of the bottom select transistor BM. The second direction Y and the third direction X are located on a plane perpendicular to the first direction Z. The second direction Y intersects with the third direction X. In this embodiment, the second direction Y is perpendicular to the third direction X. For example, the source lines SL are connected to the memory strings Str in a one-to-one correspondence through the bottom select transistors BM. Alternatively, a plurality of adjacent memory strings Str are connected to the same source line SL.

The word lines WL₁ to WLₙ are arranged along the first direction Z, where each word line WL is connected to the control terminals of the respective memory cells T-R on the same layer.

The bit lines BL are disposed above the memory strings Str. Each bit line BL extends along the second direction Y and is arranged along the third direction X. The bit line BL is connected to a second terminal of the top select transistor TM of the corresponding memory string Str arranged along the second direction Y. In this embodiment, the second terminal of the top select transistor TM is a drain terminal of the top select transistor TM.

In this embodiment, as shown in FIG. 2 and FIG. 3, the memory array 100 further includes a bottom select line SSL and a top select line DSL. The bottom select line SSL is disposed below the word lines WL₁ to WLₙ. The bottom select line SSL is connected to a control terminal of the bottom select transistor BM. The top select line DSL is disposed above the word lines WL₁ to WLₙ. The top select line DSL is connected to a control terminal of the top select transistor TM.

As shown in FIG. 2 and FIG. 3, a plurality of the memory strings Str arranged along the second direction Y are connected to a plurality of the source lines SL arranged along the second direction Y, respectively. As such, firstly, the number of memory strings Str connected by each source line SL can be reduced; secondly, each bit line BL can be connected to a plurality of memory strings Str. A column of memory strings Str connected to the same bit line BL can be connected to a plurality of source lines SL, so that parallel reading can be performed on a column of memory strings Str connected to the same bit line BL, thereby saving the read bandwidth.

In the in-memory computing architecture of this embodiment, the source lines SL are arranged along the second direction Y and the third direction X, so that the source line SL of each memory string Str can be led out independently, making the in-memory computing architecture capable of reading stored information through the source lines SL. Since the source lines SL of each memory block are independent of each other, a column of memory strings Str in a Plane has hundreds or thousands of lead-out terminals, thereby improving the potential of parallel reading.

In some embodiments, the resistance value of the bypass resistor R is greater than that of channel equivalent resistance Ron of the memory transistor T when turned on, and less than that of a channel equivalent resistance R_{off} of the memory transistor T when turned off.

The in-memory computing architecture of this embodiment can control the on-off state of the memory transistor T by controlling the magnitude of the voltage V_{WL} of a word line and a threshold voltage V_{T} of the memory transistor T. When the voltage of the word line meets V_{WL}>V_{T}, the memory transistor T is turned on, the equivalent resistance of the memory cell T-R is approximately equal to the channel equivalent resistance Rₒₙ of the memory transistor T when turned on, and the current mainly passes through the memory transistor T. When V_{WL}<V_{T}, the memory transistor T is turned off, the equivalent resistance value of the memory cell T-R is approximately equal to the resistance value of the bypass resistor R, and the current mainly passes through the bypass resistor R. Therefore, no matter the memory transistor T is turned on or off, the memory string Str where the memory cell T-R is located can always form a current path, so that when reading is performed on the memory cell T-R of the memory string Str, the number of turned-off transistors in the memory string Str can be calculated according to the voltage drop of the memory string Str.

In some embodiments, as shown in FIG. 1, along the first direction Z, the driving and sensing circuit 200 is disposed below the source line SL, and the peripheral circuit 300 is disposed above the bit line BL.

In this embodiment, the driving and sensing circuit 200 can be disposed below the memory array 100 by using CMOS Under Array (CUA). An electrical connection between the memory array 100 and the driving and sensing circuit 200 can be realized by using vias, which ensures stable transmission of current and voltage signals and maintains the overall structural compactness and reliability of the in-memory computing architecture.

In this embodiment, the peripheral circuit 300 can be integrated above the memory array 100 by using Hybrid Bonding. The Hybrid Bonding ensures high-precision and high-strength electrical and mechanical connections between the peripheral circuit 300 and the memory array 100, and ensures stable interconnection between the peripheral circuit 300 and the memory array 100.

The peripheral circuit 300 may include a page buffer, a row decoder, a column decoder, a data writing circuit, a sense amplifier circuit, a read and write control circuit, and the like. The data writing circuit is configured to implement weight writing and activation vector input to the memory array 100, so as to meet the requirements of in-memory computing.

It should be noted that CUA, namely CMOS Under Array, is a design method that places most peripheral circuits of a NAND chip (such as page buffers, read amplifiers, charge pumps, and the like) under a vertical stack of memory cells. This layout greatly saves integration space, enables more area to be used for the memory cell array, and thus improves storage density and performance.

In the in-memory computing architecture of this embodiment, the driving and sensing circuit 200 is integrated below the source lines SL. The peripheral circuit 300 is integrated above the bit lines BL, and the whole architecture is highly integrated, which can improve the performance of memories, further reduce the power consumption and cost thereof, also reduce the latency and interference of signal transmission, and improve the speed of reading and writing, and reliability of the memories. The peripheral circuit 300 is integrated above the bit lines BL, and the peripheral circuit 300 has expansion space, so that the memory can flexibly adapt to different application scenarios and performance requirements, such as in-memory computing, high-speed storage, and the like.

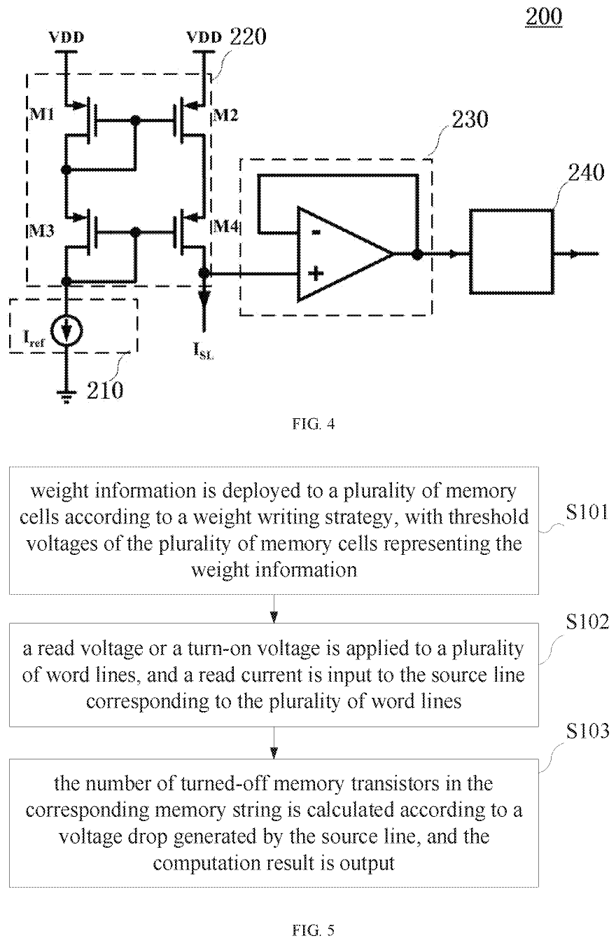

In some embodiments, as shown in FIG. 4, the driving and sensing circuit 200 includes a current generation circuit 210, a current mirror 220, and a source follower 230.

The current generation circuit 210 is configured to generate a read current I_{ref}. The current generation circuit 210 generates a constant read current I_{ref}. The stability and accuracy of the read current I_{ref} are critical to subsequent current replication and voltage sensing.

The current mirror 220 is configured to duplicate the read current I_{ref} and provide the read current I_{ref} to the source line SL. The current mirror 220 in this embodiment is a cascode current mirror. The current mirror 220 duplicates the read current I_{ref} generated by the current generation circuit 210 and provides the read current I_{ref} to the source line SL. In this embodiment, to save the area and power consumption cost of the driving and sensing circuit 200, the current mirror 220 duplicates the read current I_{ref} and then provides the read current I_{ref} to a plurality of source lines SL. Firstly, the cascode current mirror ensures high-precision replication of the read current I_{ref}, reduces the mismatch error of the current mirror, and thus ensures that a stable current can be obtained on each source line SL. Secondly, the cascode current mirror has a large output impedance and strong driving capability, which can ensure stable transmission of the current, so that the output read current I_{ref} has high stability and high accuracy.

The source follower 230 is configured to read a voltage signal of the source line SL. The source follower 230 serves as a voltage buffer and is configured to read the voltage value of the output terminal of the source line SL. The source follower 230 is further configured to isolate the memory array 100 from the analog-to-digital converter 240, to prevent the high impedance inside the memory array 100 from interfering with voltage sensing.

It should be noted that the range of the input voltage of the source follower 230 should match the memory array 100, to avoid a wide range change of the output voltage of the source line SL caused by multiple layers of word lines WL, and ensure that the voltage sensing is free from distortion and saturation. In this embodiment, the source follower 230 is implemented by a rail-to-rail operational amplifier.

The analog-to-digital converter 240 is configured to convert the voltage signal into a digital signal and output the digital signal. The analog-to-digital converter 240 converts the analog voltage signal output by the source follower 230 into a digital signal for subsequent digital signal processing.

In some embodiments, to save the area and power consumption cost of the driving and sensing circuit 200, the source follower 230 and the analog-to-digital converter 240 may be shared by a plurality of source lines SL. The driving and sensing circuit 200 further includes a multiplexer MUX. The multiplexer MUX is configured to select a source line SL that needs voltage sensing, so as to realize effective reuse of resources.

For example, the analog-to-digital converter 240 may be implemented by a Successive Approximation Register Analog-to-Digital Converter (SAR ADC).

In the in-memory computing architecture of this embodiment, by optimizing the driving and sensing circuit 200, the driving and sensing circuit 200 can provide a constant read current I_{ref} to the source line SL and accurately sense the voltage thereof, which provides a reliable basis for the voltage-domain in-memory computing of the in-memory computing architecture, and ensures effectiveness and reliability thereof in in-memory computing applications.

In some embodiments, as shown in FIG. 1, the in-memory computing architecture further includes a control logic circuit 400. The control logic circuit 400 is connected to the driving and sensing circuit 200 and the peripheral circuit 300. The control logic circuit 400 is connected to the driving and sensing circuit 200 to receive a digital signal from the driving and sensing circuit 200. The digital signal reflects the state of the memory cell T-R in the memory array 100. The control logic circuit 400 is connected to the peripheral circuit 300. The control logic circuit 400 controls the voltages of the word line WL and the bit line BL through the peripheral circuit 300, thereby realizing reading and writing of the memory cell T-R.

The control logic circuit 400 is configured to deploy weight information to the memory cell T-R according to a weight writing strategy, with a threshold voltage of the memory cell T-R representing the weight information. For example, different threshold voltages may correspond to different weight values to realize data writing to the memory cell T-R. A read voltage V_{read} or a turn-on voltage Vₚₐₛₛ can be applied to the word line WL, and a read current I_{ref} can be input to the source line. The number of turned-off memory transistors T in the memory string Str can be calculated according to a voltage drop ΔV generated by the source line SL. A computation result can be output. When the read current I_{ref} passes through the memory string Str, a corresponding voltage drop is generated on the source line SL due to different on-off states of the memory transistors T (i.e., different threshold voltages). The control logic circuit 400 senses the voltage drop ΔV, and calculates the number of turned-off memory transistors T in the memory string Str according to the magnitude of the voltage drop ΔV. The control logic circuit 400 outputs the computation result for subsequent processing or application.

The control logic circuit 400 implements data transmission with the driving and sensing circuit 200 and the peripheral circuit 300 by using the ONFI 5.0 protocol. The control logic circuit 400 communicates with a terminal by using the PCIe 5.0 protocol.

In the in-memory computing architecture of this embodiment, the control logic circuit 400 deploys weight information, calculates the voltage drop ΔV, and outputs the computation result. The word line WL is configured as an input terminal, and the source line SL is configured as an output terminal. By applying different read voltages V_{read} and turn-on voltages Vₚₐₛₛ to respective word lines WL and providing a read current I_{ref} to the source lines SL, the architecture can directly perform computing tasks inside the memory cells T-R, realize parallel computing of data in the memory cells T-R, process multiple data values at the same time, and further improve the computing efficiency. The in-memory computing architecture of the present disclosure has the following beneficial effects: the in-memory computing architecture of the present disclosure integrates a memory array, a driving and sensing circuit, and a peripheral circuit, and realizes a high integration of data storage and computation. The in-memory computing architecture can directly process the data inside the memory array without reading the data out to an external processor for computation, and avoid latency and power consumption caused by external data transmission. The in-memory computing architecture of this embodiment can perform computation tasks by using the structure of the memory array, perform operations on multiple memory strings in parallel, read the computation result from the source line by detecting a voltage change of the source line corresponding to each memory cell, and achieve high computation efficiency.

In an embodiment, an operating method of the in-memory computing architecture is provided in the present disclosure. The operating method provided in this embodiment is performed based on the in-memory computing architecture of the above embodiments. As shown in FIG. 5, the operating method of the in-memory computing architecture includes the following Step S101 to Step S103.

At Step S101, weight information is deployed to a plurality of memory cells according to a weight writing strategy, with threshold voltages of the plurality of memory cells representing the weight information.

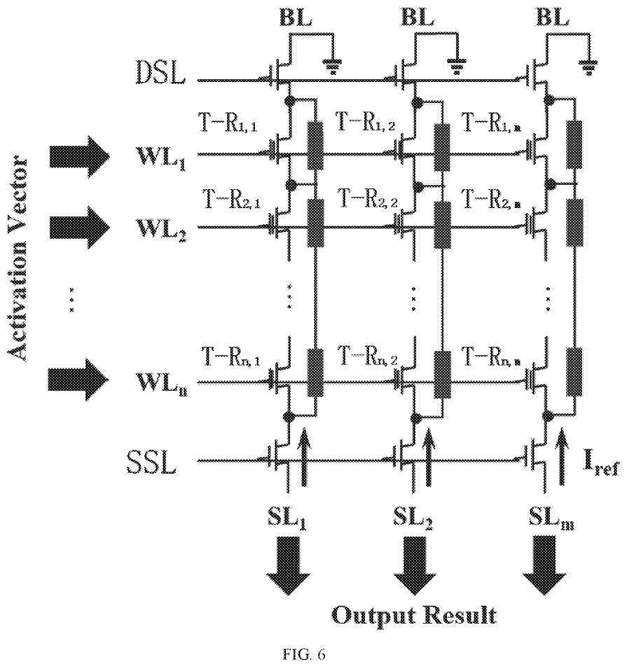

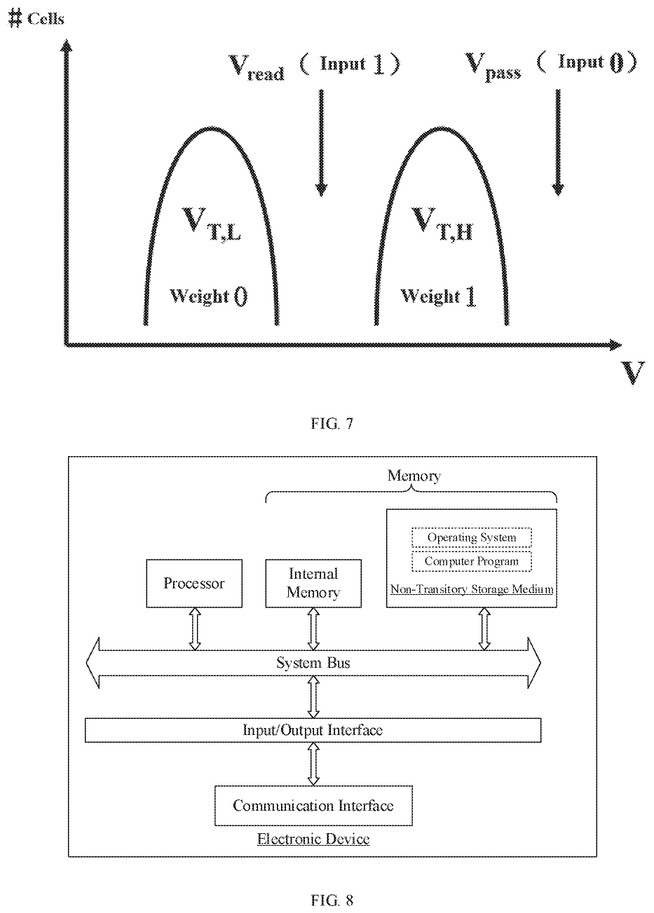

In this embodiment, referring to FIG. 6 and FIG. 7, and in conjunction with FIG. 1 to FIG. 4, the control logic circuit 400 deploys the weight information to the memory cells according to the weight writing strategy. The weight information can be generated by a terminal (such as a neural network processor, a central processing unit, and the like) and transmitted to the control logic circuit 400, or the weight information can be stored in an external database. The control logic circuit 400 obtains the weight information by accessing the database.

The weight writing strategy can also be stored in a database, and the weight writing strategy defines how to map the weight information to the threshold voltages of the memory cells T-R. The control logic circuit 400 obtains the weight writing strategy by accessing the database.

The control logic circuit 400 adjusts the voltages of the bit lines BL and the word lines WL through the peripheral circuit 300 according to the weight writing strategy, to set the threshold voltages of the memory cells T-R to characterize the weight information. The control logic circuit 400 deploys the weight information to the corresponding memory cells T-R of the memory array 100. The control logic circuit 400 sets the threshold voltages of the memory transistors T of the memory cells T-R to values corresponding to the weight information.

At Step S102, a read voltage or a turn-on voltage is applied to a plurality of word lines, and a read current is input to the source line corresponding to the plurality of word lines.

In this embodiment, referring to FIG. 6 and FIG. 7, and in conjunction with FIG. 1 to FIG. 4, the control logic circuit 400 controls the peripheral circuit 300 to apply a read voltage V_{read} or a turn-on voltage Vₚₐₛₛ to the word line WL. The read voltage V_{read} is configured to sense the state of the memory cell T-R. The turn-on voltage Vₚₐₛₛ is configured to turn on the memory transistor T of the memory cell T-R when required. The control logic circuit 400 controls the driving and sensing circuit 200 to input a read current I_{ref} to the source line SL to be detected. The read current I_{ref} is configured to generate a voltage drop ΔV in the memory string Str, to reflect the state of the memory cell T-R.

In this embodiment, the control logic circuit 400 can input an activation vector corresponding to the respective word lines WL to the peripheral circuit 300. The activation vector determines the corresponding word lines WL receiving the read voltage V_{read} and the corresponding word lines WL receiving the turn-on voltages Vₚₐₛₛ in the memory array 100.

At Step S103, the number of turned-off memory transistors in the corresponding memory string is calculated according to a voltage drop generated by the source line, and the computation result is output.

In this embodiment, referring to FIG. 6 and FIG. 7, and in conjunction with FIG. 1 to FIG. 4, the driving and sensing circuit 200 is based on the voltage drop ΔV generated by the source line SL, where the magnitude of the voltage drop ΔV is directly related to the number of turned-off memory transistors T in the corresponding memory string Str. According to the voltage drop ΔV generated on the source line SL, the driving and sensing circuit 200 calculates the number of turned-off memory transistors T in the memory string Str, and outputs the computation result to the control logic circuit 400. The control logic circuit 400 may further process the computation result and transmit the computation result to a terminal or other processing units for subsequent use. Terminals may include, but are not limited to, various personal computers, notebook computers, smartphones, tablet computers, Internet of Things devices, and portable wearable devices. The Internet of Things devices may be smart speakers, smart TVs, smart air conditioners, smart in-vehicle devices, projection devices, and the like. The portable wearable devices may be smart watches, smart bracelets, head-mounted devices, and the like.

The operating method of the in-memory computing architecture of this embodiment realizes a voltage-domain-based in-memory computing strategy by using the in-memory computing architecture. The operating method characterizes weight information by controlling the threshold voltages of the memory cells T-R, and the number of turned-off memory transistors T in the memory string Str can be quickly calculated by detecting the voltage drop ΔV on the source line SL, which not only improves computation parallelism and computation efficiency, but also reduces the power consumption of data transmission, and provides support for computation-intensive applications such as neural networks.

In some embodiments, Step S101 of deploying weight information to memory cells according to a weight writing strategy, with threshold voltages of the memory cells representing the weight information includes Step S101-1 and Step S101-2.

At Step S101-1, a plurality of weight elements of a weight matrix are encoded into binary values of weight 1 or weight 0.

In this embodiment, referring to FIG. 7, the weight matrix can be generated by a terminal or stored in an external database. The terminal encodes each weight element of the weight matrix into a binary value of weight 1 or weight 0. The terminal encodes each element in the weight matrix into a binary value according to the numerical value of the weight element; for example, the weight element may be obtained through neural network training.

In this embodiment, the weight matrix is a floating-point weight matrix, and the weight elements in the weight matrix are represented by floating-point numbers. The continuous floating-point weight elements are converted into discrete binary values through neural network training, by quantization (selection of quantization range and/or determination of quantization bit width), scaling, and rounding.

At Step S101-2, a program voltage or an erase voltage is applied to each of the plurality memory cells corresponding to each of the plurality of weight elements according to a mapping relationship between the weight matrix and the plurality of memory cells, and a threshold voltage of each of the plurality of memory cells is adjusted to a higher threshold voltage or a lower threshold voltage. The higher threshold voltage corresponds to weight 1. The lower threshold voltage corresponds to weight 0.

In this embodiment, referring to FIG. 7, the mapping relationship between the weight matrix and the memory cells is an address mapping mechanism between each weight element of the weight matrix and the corresponding memory cell T-R of the memory array 100, to ensure that each weight element can uniquely correspond to one memory cell T-R. The mapping relationship between the weight matrix and the memory cells may be generated by a terminal or stored in a database.

The control logic circuit 400 controls the peripheral circuit 300 to apply the program voltage or the erase voltage to the corresponding memory cells T-R according to the weight element obtained by encoding the binary values of the weight matrix and the mapping relationship between the weight matrix and the memory cells T-R. The memory transistor T of the memory cell T-R enters a corresponding program state or erase state, thereby storing the weight information in the form of the threshold voltages.

In this embodiment, an erase voltage is applied to each word line WL of the memory array 100. Then, for the memory cells T-R corresponding to weight 1, the control logic circuit 400 controls the peripheral circuit 300 to apply a program voltage to the corresponding word lines WL, to adjust the threshold voltages of the memory cells T-R corresponding to weight 1 to a higher threshold voltage V_{T,H}. Thus, the threshold voltages of the memory cells T-R corresponding to weight 1 are the higher threshold voltage V_{T,H}, and the threshold voltages of the memory cell T-R corresponding to weight 0 are the lower threshold voltage V_{T,L}.

In this embodiment, before computing, all weight elements of the weight matrix are encoded bit by bit and deployed to corresponding positions in the memory array 100. Thus, each memory cell T-R stores 1-bit information of the corresponding weight element through the memory transistor T. The information of the weight element is represented by one of the two threshold voltage states of the memory transistor T. The higher threshold voltage V_{T,H} corresponds to weight 1 and the lower threshold voltage V_{T,L} corresponds to weight 0. This provides a basis for subsequent in-memory computing, so that the weight information can directly participate in the calculation in the memory cells T-R, thereby improving the computation efficiency and reducing the power consumption.

In some embodiments, applying a read voltage or a turn-on voltage to a plurality of word lines of Step S102 includes Step S102-1 and Step S102-2.

At Step S102-1, each element of an activation vector is encoded into a binary value.

In this embodiment, the activation vector may be generated by a terminal, or the activation vector may be stored in a database. The terminal obtains the activation vector by accessing the database. The terminal encodes each element of the activation vector into a binary activation value 1 or a binary activation value 0. Similarly, the encoding of the activation vector may be obtained through neural network training.

In this embodiment, the activation vector is a floating-point activation value matrix. Activation values in the activation vector are represented by floating-point numbers. The floating-point numbers are input from the outside or generated by an upper-layer neural network. The continuous floating-point activation values are converted into discrete binary values by quantization (selection of quantization range and/or determination of quantization bit width), scaling, and rounding.

At Step S102-2, the read voltages V_{read} are applied to the word lines corresponding to the encoded activation values 1. The turn-on voltages Vₚₐₛₛ are applied to the word lines corresponding to the encoded activation value 0 according to a mapping relationship between the activation vector and the word lines, where the turn-on voltages Vₚₐₛₛ are greater than the read voltages V_{read}.

In this embodiment, the mapping relationship between the activation vector and the word lines is an address mapping mechanism between each element of the activation vector and each word line WL, to ensure that each activation value of the activation vector can uniquely correspond to one word line WL. The mapping relationship between the weight activation vector and the word lines WL may be generated by a terminal or stored in a database.

The control logic circuit 400 controls the peripheral circuit 300 to input the read voltage V_{read} or the turn-on voltage Vₚₐₛₛ to the corresponding word line WL according to the activation value encoded from the activation vector and the mapping relationship between the activation vector and the word line.

For the encoded activation value 1, the control logic circuit 400 controls the peripheral circuit 300 to apply the read voltage V_{read} to the corresponding word line WL. The read voltage V_{read} can keep the memory transistor T connected to the word line WL, with a lower threshold voltage (i.e., storing the weight 0) in an on state, but turn off the memory transistor T with a higher threshold voltage (i.e., storing the weight 1).

For the encoded activation value 0, the control logic circuit 400 controls the peripheral circuit 300 to apply a relatively high voltage, i.e., the turn-on voltage Vₚₐₛₛ, to the corresponding word line WL. The turn-on voltage Vₚₐₛₛ ensures that the memory transistor T can remain in an on state regardless of whether the threshold voltage of the memory transistor T is high or low.

It should be noted that the turn-on voltage Vₚₐₛₛ is greater than the read voltage V_{read}, to ensure that the memory transistor T can be successfully turned on when the activation value is 0.

In this embodiment, V_{T,L}<V_{read}<V_{T,H}<Vₚₐₛₛ. Only when the threshold voltage of the memory transistor T is equal to V_{T,H} and the voltage of the word line is equal to V_{read}, the memory transistor T in the memory cell T-R is in an off state and generates a voltage drop across two sides of the memory cell T-R. The memory transistor T is in the on state in other cases.

In this embodiment, the information of the activation vector is mapped to the voltages of the word lines WL, which provides a basis for subsequent in-memory computing, so that the activation values can directly participate in the computing in the memory cells T-R, thereby improving the computation efficiency and reducing the power consumption.

In some embodiments, a read voltage V_{read} or a turn-on voltage Vₚₐₛₛ is applied to the word line WL and a read current I_{ref} is input to the source line SL further includes adjusting the voltage of the word line WL and the read current I_{ref}, so that when the memory transistor T is turned on, the current of the memory cell T-R flows through the memory transistor T. When the memory transistor T is turned off, the current of the memory cell T-R flows through the bypass resistor R, to generate a voltage drop ΔV across two sides of the memory cell T-R.

The voltage drops ΔV generated by turned-off memory transistors T are accumulated along the corresponding memory string Str, and finally form an output voltage V_{SL} on the source line SL. The magnitude of the output voltage V_{SL} is proportional to the number of turned-off memory transistors T in the corresponding memory string Str. The number of turned-off memory transistors T in the corresponding memory string Str is equal to the value obtained by performing multiplication on the respective memory cells T-R of the corresponding memory string Str and the input information of the word lines WL, and then performing a summation on the multiplications.

In some embodiments, calculating the number of turned-off memory transistors T in the corresponding memory string Str according to the voltage drop ΔV generated by the source line SL and outputting a computation result of Step S103 includes Step S103-1 and Step S103-2.

At Step S103-1, a multiplication is performed on the weight elements of the corresponding memory cells and the activation values of the corresponding word lines connected to the corresponding memory cells, to obtain a voltage drop of the memory cell as 1 or 0.

In this embodiment, the control logic circuit 400 performs the multiplication on the weight elements of the memory cells T-R and the activation values of the word lines WL connected to the corresponding memory cells T-R. When the weight elements of the corresponding memory cells T-R each are 1 (i.e., when the memory transistors T of the corresponding memory cells T-R are turned off) and the activation values of the corresponding word lines WL connected to the corresponding memory cells T-R each are 1 (i.e., the read voltage V_{read} is applied to the word lines WL), the voltage drops of the corresponding memory cells T-R are each obtained as 1.

When the weight elements of the memory cells T-R each are 0 (i.e., when the memory transistors T of the corresponding memory cells T-R are turned on) and/or the activation values of the corresponding word lines WL connected to the corresponding memory cells T-R each are 0 (i.e., the turn-on voltages Vₚₐₛₛ are applied to the corresponding word lines WL), the voltage drops of the corresponding memory cells T-R are each obtained as 0.

At Step S103-2, a summation is performed on the voltage drops of the memory cells of the memory string to obtain the number of turned-off memory transistors in the memory string.

In this embodiment, based on the structure of the memory array 100, the voltage drops of all memory cells T-R in the memory string Str are accumulated for the summation. Since each memory cell T-R with a turned-off memory transistor T will generate a voltage drop in the memory string Str, the result of the summation can represent the number of turned-off memory transistors T in the memory string Str.

For example, there are n memory cells T-R in the memory string Str, where the memory transistors T of m memory cells T-R are turned off. Then the m turned-off memory transistors T generate m voltage drops, and these voltage drops can be accumulated together to obtain a total voltage drop value of the memory string Str. The number m of turned-off memory transistors T in the memory string Str can be obtained according to the total voltage drop value.

The operating method of the in-memory computing architecture of this embodiment realizes obtaining the computation result of Vector Matrix Multiplication (VMM) expressed in the form of voltage by providing constant read currents I_{ref} to the memory strings Str, grounding all bit lines BL, and sensing the voltages of the source lines SL, which improves the sensing accuracy, and provides strong support for the further application and development of VMM.

To facilitate further understanding of the solution of the present disclosure, referring to FIG. 1 to FIG. 7, an in-memory computing architecture and an operating method thereof provided in the present disclosure are described as follows.

In the in-memory computing architecture of this embodiment, the stacked storage number N of the memory array 100 is 232, that is, each memory string Str includes 232 vertically stacked memory cells T-R. The memory array 100 includes 232 word lines WL₁ to WL₂₃₂.

Each memory string Str is connected to one source line SL through one bottom select transistor BM. The memory strings Str are connected to the source lines SL in a one-to-one correspondence. In this embodiment, the source lines SL corresponding to the memory cells Str of the same storage page are led out independently. Each storage page has m memory strings Str. The m memory strings Str are correspondingly connected to m source lines SL₁ to SLₘ, respectively. For example, each storage page includes 128k memory strings Str, and the 128k memory strings Str of each storage page are connected to 128k source lines, respectively, that is, the total number of output terminals m equals 128k.

In other embodiments, 3 to 4 memory strings Str sequentially arranged in the same storage page may share one output terminal, which has relatively low difficulty of manufacturing process and relatively low manufacturing cost.

Each memory cell T-R includes a memory transistor T and a bypass resistor R connected in parallel with a memory transistor T. Along the first direction Z, the memory transistors T of the memory string Str are connected in series sequentially, and the bypass resistors R are connected in series sequentially as well.

The resistance value of the bypass resistor R is much greater than the channel equivalent resistance Rₒₙ of the memory transistor T when turned on, and much less than the channel equivalent resistance R_{off} of the memory transistor T when turned off.

The channel equivalent resistance R_{off} of the memory transistor T when turned off is approximately infinite. In this embodiment, the resistance value of the bypass resistor R of the memory cell T-R meets the requirement of Rₒₙ<<R<<R_{off}.

When the operating method is performed on the in-memory computing architecture of this embodiment, the word line WL is configured as an input terminal, and the source line SL is configured as an output terminal.

The weight information is deployed to the memory cells T-R according to a weight writing strategy, with the threshold voltages of the memory transistors T of the memory cells T-R representing the weight information.

According to the corresponding relationship between the activation vector and the word lines WL, each activation value is input to the corresponding word line WL. The read voltage V_{read} or the turn-on voltage Vₚₐₛₛ is applied to the corresponding word line WL. The read currents I_{ref} are input to the source lines SL, respectively.

When a memory transistor T of the memory cell T-R in a certain layer is turned off, a voltage drop ΔV=I_{ref}·R is generated across two sides of the memory cell T-R. The voltage drops across two sides of respective memory cells T-R are accumulated along the memory string Str, and finally, an output voltage V_{SL} is output through the source line SL. The magnitude of the output voltage V_{SL} is proportional to the number of turned-off memory transistors T in the memory string Str.

In the operating method of this embodiment, the number of memory cells T-R that can participate in calculation in parallel at one time is the product of the total number of the word lines WL and the total number of the source lines SL, that is, n×m. Combined with the horizontal expansion of memory arrays 100, the total number of the memory cells T-R that can actually participate in the calculation in parallel is equal to the number of all memory cells T-R of the memory array 100. For example, for a Quad-Level Cell (QLC) memory array with a storage capacity of 1 Tb, the total number of memory cells that can participate in the calculation in parallel can reach 256 M, which greatly increases the upper limit of the parallelism of the in-memory computing strategy. The voltage-domain-based in-memory computing strategy of this embodiment increases the parallelism potential by several times compared with the original.

The operating method of the in-memory computing architecture provided in the present disclosure has the following beneficial effects: the operating method of the in-memory computing architecture of the present disclosure realizes a voltage-domain-based in-memory computing strategy by using the in-memory computing architecture, characterizes weight information by controlling threshold voltages of memory cells, and quickly calculates the number of turned-off memory transistors in the memory string by detecting voltage drops on source lines, which not only improves computation parallelism and computation efficiency, but also reduces power consumption of data transmission, and provides support for computation-intensive applications such as neural networks.

In some embodiments, an electronic device is provided. As shown in FIG. 8, the electronic device may be a terminal. The electronic device includes a controller and a processor. The controller stores a computer program. The processor implements the steps of the operating method of the in-memory computing architecture in the above embodiments when executing the computer program.

The internal structure diagram of the electronic device may be as shown in FIG. 8. The electronic device includes a processor, a controller, an Input/Output (I/O) interface, and a communication interface. The processor, the controller, and the input/output interface are connected through a system bus. The communication interface is connected to the system bus through the input/output interface. The processor of the electronic device is configured to provide computing and control capabilities. The controller of the electronic device includes a non-volatile storage medium and an internal memory. The non-volatile storage medium stores an operating system, a computer program, and a database. The internal memory provides an environment for the running of the operating system and the computer program in the non-volatile storage medium. The input/output interface of the electronic device is configured to exchange information between the processor and an external device. The communication interface of the electronic device is configured to connect and communicate with an external terminal through a network. The computer program is executed by the processor to implement the operating method of the in-memory computing architecture.

Those skilled in the art can understand that the structure shown in FIG. 8 is only a block diagram of a partial structure related to the solution of the present application, and does not constitute a limitation on the electronic device to which the solution of the present application is applied. A specific electronic device may include more or fewer components than those shown in the drawings, combine some components, or have a different component arrangement.

It should be noted that the information (including but not limited to information of the electronic device) and data (including but not limited to data for analysis, stored data, displayed data, and the like) involved in the present disclosure are all information and data authorized by a user or fully authorized by all parties. The collection, use, or processing of relevant data complies with relevant regulations.

Those of ordinary skill in the art can understand that all or part of the processes in the operating method of the above embodiments can be implemented by a computer program instructing relevant hardware. The computer program can be stored in a non-volatile computer-readable storage medium. When executed, the computer program can include the processes of the operating method provided in the above embodiments. Any reference to the controller, the database, or other media used in the embodiments provided in the present disclosure may include at least one of a non-volatile memory or a volatile memory. Non-volatile memory may include Read-Only Memory (ROM), magnetic tape, floppy disk, flash memory, optical memory, high-density embedded non-volatile memory, Resistive Random Access Memory (ReRAM), Magnetoresistive Random Access Memory (MRAM), Ferroelectric Random Access Memory (FRAM), Phase Change Memory (PCM), graphene memory, and the like. Volatile memory may include Random Access Memory (RAM), external cache memory, and the like. By way of illustration and not limitation, RAM may be in many forms, such as Static Random Access Memory (SRAM), Dynamic Random Access Memory (DRAM), and the like. The databases involved in the various embodiments provided in the present disclosure may include at least one of a relational database and a non-relational database. Non-relational database may include, but is not limited to, distributed database based on blockchain, and the like. The processor involved in the various embodiments provided in the present disclosure may include, but is not limited to, a general-purpose processor, a central processing unit, a graphics processing unit, digital signal processor, a programmable logic device, and the like.

The technical features of the above embodiments can be combined arbitrarily. For brevity of description, all possible combinations of the technical features of the above embodiments are not described. However, as long as there is no contradiction in the combination of these technical features, it should be considered that such a combination falls within the scope of this specification.

The above embodiments merely represent several implementations of the solution provided in the present disclosure, and the description thereof is relatively detailed, but should not be construed as limiting the technical solution of the patent disclosure. It should be noted that, for those of ordinary skill in the art, some variations and improvements can be made without departing from the inventive concept of the present disclosure. These variations and improvements all fall within the scope of the present disclosure.

What is claimed is:

1. An in-memory computing architecture, comprising:
a memory array, comprising:
a plurality of memory strings;
a plurality of source lines;
a plurality of word lines; and
a plurality of bit lines; wherein each of the plurality of memory strings comprises a plurality of memory cells connected in series along a first direction, each of the plurality of memory cells comprises a memory transistor and a bypass resistor, the memory transistor and the bypass resistor are connected in parallel, each of the plurality of memory strings is connected to the corresponding source line of the plurality of source lines through a bottom select transistor, each of the plurality of memory strings is connected to the corresponding bit line of the plurality of bit lines through a top select transistor, and a control terminal of each of the plurality of memory cell is connected to the corresponding word line;
a driving and sensing circuit, connected to the source line, wherein the driving and sensing circuit is configured to provide a read current to the source line, sense a voltage signal of the source line, and output a digital signal of the voltage signal of the source line; and
a peripheral circuit, connected to the word lines and the bit lines, wherein the peripheral circuit is configured to control voltages of the word lines and the bit lines.

2. The in-memory computing architecture according to claim 1, wherein each of the plurality of source lines is disposed below the corresponding memory string of the plurality of memory strings, the plurality of source lines are arranged along a second direction and a third direction perpendicular to the first direction, and each of the plurality of source lines is connected to a first terminal of the bottom select transistor of the corresponding memory string of the plurality of memory strings;
the plurality of word lines are arranged along the first direction, each of the plurality of word lines is connected to the control terminal of the corresponding memory cell of the plurality of memory cells, each of the plurality of word lines and the corresponding memory cell are arranged on the same layer, and
each of the plurality of bit lines is disposed above the corresponding memory string of the plurality of memory strings, each of the plurality of bit lines extends along the second direction and is arranged along the third direction, and each of the bit lines is connected to a second terminal of the top select transistor of the corresponding memory string arranged along the second direction;
wherein the plurality of the memory strings arranged along the second direction are connected to the plurality of the source lines arranged along the second direction, respectively.

3. The in-memory computing architecture according to claim 1, wherein a resistance value of the bypass resistor is greater than a channel equivalent resistance value of the memory transistor when turned on, and less than a channel equivalent resistance value of the memory transistor when turned off.

4. The in-memory computing architecture according to claim 3, wherein along the first direction, the driving and sensing circuit is integrated below the plurality of source lines, the peripheral circuit is integrated above the plurality of bit lines, and the driving and sensing circuit comprises:
a current generation circuit, configured to generate a read current;
a current mirror, configured to duplicate the read current and provide the read current to the source line;
a source follower, configured to read the voltage signal of the source line; and
an analog-to-digital converter, configured to convert the voltage signal into the digital signal and output the digital signal.

5. The in-memory computing architecture according to claim 1, further comprising:
a control logic circuit, connected to the driving and sensing circuit and the peripheral circuit;
wherein the control logic circuit is configured to:
deploy weight information to the plurality of memory cells according to a weight writing strategy, with a threshold voltage of the memory cell representing the weight information;
apply read voltages or turn-on voltages to the plurality of word lines, and input a read current to the plurality of source lines corresponding to the plurality of word lines;
calculate the number of turned-off memory transistors in the corresponding memory string according to a voltage drop generated by the source line and output a computation result.

6. The in-memory computing architecture according to claim 1, wherein the memory array further comprises a bottom select line and a top select line, the bottom select line is disposed below the plurality of word lines and connected to a control terminal of the bottom select transistor, and the top select line is disposed above the plurality of word lines and connected to a control terminal of the top select transistor.

7. The in-memory computing architecture according to claim 1, wherein along the first direction, the memory transistors of the plurality of memory cells in each of the plurality of memory strings are connected in series sequentially, and the bypass resistors of the plurality of memory cells are connected in series sequentially.

8. The in-memory computing architecture according to claim 2, wherein the plurality of memory strings are connected to the plurality of source lines in a one-to-one correspondence through the bottom select transistors.

9. The in-memory computing architecture according to claim 2, wherein the plurality of memory strings that are sequentially arranged along the third direction share the same source line of the plurality of source lines.

10. The in-memory computing architecture according to claim 4, wherein the source follower and the analog-to-digital converter are shared by the plurality of the source lines.

11. The in-memory computing architecture according to claim 1, wherein the peripheral circuit comprises:
a page buffer;
a row decoder;
a column decoder;
a data writing circuit;
a sense amplifier circuit; and
a read and write control circuit;
wherein the data writing circuit is configured to write weight information and input an activation vector to the memory array.

12. The in-memory computing architecture according to claim 4, wherein the peripheral circuit is integrated above the plurality of bit lines through hybrid bonding.

13. An operating method of an in-memory computing architecture, the in-memory computing architecture comprising a memory array, a driving and sensing circuit, and a peripheral circuit; the memory array comprising a plurality of memory strings, a plurality of source lines, a plurality of word lines, and a plurality of bit lines; each of the plurality of memory strings comprising a plurality of memory cells connected in series along a first direction; each of the plurality of memory cell comprising a memory transistor and a bypass resistor; the memory transistor and the bypass resistor being connected in parallel; each of the plurality of memory strings being connected to the corresponding source line of the plurality of source lines through a bottom select transistor; each of the plurality of memory strings being connected to the corresponding bit line of the plurality of bit lines through a top select transistor; a control terminal of each of the plurality of memory cell being connected to the corresponding word line; the driving and sensing circuit connected to the source line; the driving and sensing circuit being configured to provide a read current to the source line, sense a voltage signal of the source line, and output a digital signal of the voltage signal of the source line; the peripheral circuit connected to the word lines and the bit lines; and the peripheral circuit being configured to control voltages of the word lines and the bit lines;
wherein the operating method of the in-memory computing architecture comprises:
deploying weight information to the plurality of memory cells according to a weight writing strategy, with threshold voltages of the plurality of memory cells representing the weight information;
applying read voltages or turn-on voltages to the plurality of word lines, and inputting a read current to the source line corresponding to the plurality of word lines; and
calculating the number of turned-off memory transistors in the corresponding memory string according to a voltage drop generated by the source line, and outputting a computation result.

14. The operating method of the in-memory computing architecture according to claim 13, wherein the step of deploying weight information to the plurality of memory cells according to a weight writing strategy comprises:
encoding a plurality of weight elements of a weight matrix into binary values of a weight 1 or a weight 0; and
applying a program voltage or an erase voltage to each of the plurality of memory cells corresponding to each of the plurality of weight elements according to a mapping relationship between the weight matrix and the plurality of memory cells, and adjusting a threshold voltage of each of the plurality of memory cells to a higher threshold voltage or a lower threshold voltage, wherein the higher threshold voltage corresponds to the weight 1, and the lower threshold voltage corresponds to the weight 0.

15. The operating method of the in-memory computing architecture according to claim 14, wherein the step of applying read voltages or turn-on voltages to the plurality of word lines comprises:
encoding a plurality of weight elements of each activation vector of the weight matrix into binary values; and
applying the read voltages to word lines corresponding to encoded activation values 1, and applying the turn-on voltages to word lines corresponding to encoded activation values 0, according to a mapping relationship between the activation vector and the plurality of word lines, wherein the turn-on voltages are greater than the read voltages.

16. The operating method of the in-memory computing architecture according to claim 13, wherein the step of applying read voltages or turn-on voltages to the plurality of word lines, and inputting a read current to the source line further comprises:
adjusting the turn-on voltages and read current of the plurality of word lines, so that when the memory transistor is turned on, a current of the memory cell flows through the memory transistor, and when the memory transistor is turned off, the current of the memory cell flows through the bypass resistor, to generate a voltage drop across two sides of the memory cell.

17. The operating method of the in-memory computing architecture according to claim 16, wherein the step of calculating the number of turned-off memory transistors in the corresponding memory string according to a voltage drop generated by the source line, and outputting a computation result comprises:
performing a multiplication on the plurality of weight elements corresponding to the plurality of memory cells and activation values of the plurality of word lines connected to the plurality of memory cells, respectively, to obtain voltage drops of the memory cells as each of 1 or 0; and
performing an addition on the voltage drops of the plurality of memory cells of each of the plurality of memory strings, to obtain the number of turned-off memory transistors in each of the plurality of memory strings.

18. The operating method of the in-memory computing architecture according to claim 15, wherein the lower threshold voltage is less than the read voltage, the read voltage is less than the higher threshold voltage, and the higher threshold voltage is less than the turn-on voltage.

19. The operating method of the in-memory computing architecture according to claim 14, wherein the step of adjusting a threshold voltage of each of the plurality of memory cells to a higher threshold voltage or a lower threshold voltage comprises:
firstly, applying an erase voltage to the plurality of word lines of the memory array to initialize the threshold voltages of the plurality of memory cells to a lower threshold voltage; and
then, applying a program voltage to the plurality of memory cells corresponding to the weight 1, to adjust the threshold voltages of the plurality of memory cells corresponding to the weight 1 to the higher threshold voltage.

20. A memory array, comprising:
a plurality of memory strings;
a plurality of source lines;
a plurality of word lines; and
a plurality of bit lines,
wherein each of the plurality of memory strings comprises a plurality of memory cells connected in series along a first direction, each of the plurality of memory cells comprises a memory transistor and a bypass resistor, the memory transistor and the bypass resistor are connected in parallel, each of the plurality of memory strings is connected to the corresponding source line of the plurality of source lines through a bottom select transistor, each of the plurality of memory strings is connected to the corresponding bit line of the plurality of bit lines through a top select transistor, and a control terminal of each of the plurality of memory cell is connected to the corresponding word line.
